(19) United States
(12) Patent Application Publication
(10) Pub. No.: US 2007/0212804 A1
(43) Pub. Date: Sep. 13, 2007

(54) SOLID-STATE IMAGING DEVICE AND METHOD FOR MANUFACTURING THEREOF

(75) Inventors: Syu Sasaki, Kitakami-City (JP); Katsuhiro Kanno, Kitakami-City (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/685,406

(22) Filed: Mar. 13, 2007

(30) Foreign Application Priority Data
Mar. 13, 2006 (JP) JP2006-067216

(51) Int. Cl. H01L 21/00

(52) U.S. Cl. 438/29

(57) ABSTRACT

A solid-state imaging device is formed by laminating a photodiode on a surface of a Si semiconductor substrate, a gate electrode layer to read out or transfer electric charge stored on the photodiode, a first inter-layer insulating film made of SiO2, a first metallic wiring layer, a second inter-layer insulating film made of SiO2, a second metallic insulating layer, an undoped silicon glass (USG) film containing hydrogen, and a passivation film containing hydrogen, one by one. Dark currents are reduced by exhausting hydrogen atoms in the USG film and the passivation film for bonding it with dangling bonds on the surface of the Si semiconductor substrate, while applying heat treatments to the imaging device at a temperature of 400° C. or higher.

### CROSS-REFERENCE TO RELATED APPLICATIONS

This application is based upon and claims the benefit of priority from the prior Japanese Patent Application No. 2006-067216, filed Mar. 13, 2006, the entire contents of which are incorporated herein by reference.

### BACKGROUND OF THE INVENTION

The present invention relates to a solid-state imaging device and a method for manufacturing it, and more specifically, relates to a solid-state imaging device and a method for manufacturing it, in which it is possible to reduce dark currents.

In a solid-state imaging device using a CCD or a C-MOS sensor, such a semiconductor device structure as amorphous Si has been used, which has no periodicity in its atomic arrangement and has a large number of dangling bonds not taking part in atomic bonds on an interface of a SiO2/Si structure. In the case in which such dangling bonds exist, the existence of an interface state causes dark currents in manufacturing steps of the solid-state imaging device.

Therefore, conventionally, a technique has been adopted in a final step of manufacturing a semiconductor device to reduce a function to trap other atoms, for instance, impurities to be added to give a semiconductor a certain characteristic, in which a film of silicon nitride (SiN) is formed including a quantity of 1.0 E21 or larger of hydrogen as a whole, applying a heat treatment to exhaust the hydrogen from the film of silicon nitride and to have it diffused into a Si substrate to bond with the dangling bonds (refer to Japanese Published Patent Application H8-45926).

With the recent advance of refining of cells composing the solid-state imaging device, a fine process of metallic wiring has been required. Thus, a barrier metallic wiring structure, such as Ti/TiN, has been widely used. In the solid-state imaging device with such a barrier metallic wiring structure adopted, there is a problem that the dark currents cannot be sufficiently reduced since a sufficient quantity of the hydrogen atoms is not supplied to the dangling bonds in the Si substrate due to a block phenomenon of hydrogen atoms by the barrier metallic wiring, if it is intended to exhaust hydrogen through a heat treatment in the final step of the foregoing manufacture of the solid-state imaging device.

One of the objects of the present invention is to provide a solid-sate imaging device and its manufacturing method capable of fully reducing the dark currents by solving the problem in the solid-state imaging device adopting such a barrier metallic wiring structure.

### BRIEF SUMMARY OF THE INVENTION

A solid-state imaging device according to an aspect of the invention includes a photodiode which is formed on a surface of a semiconductor substrate; a gate electrode layer which is formed on the surface of the semiconductor substrate through a gate oxide film; a first inter-layer insulating film which is formed on the surface of the semiconductor substrate with the photodiode and the gate electrode layer formed thereon; a first metallic wiring layer formed on the surface of the first inter-layer insulating film at portions other than upper portions of the photodiode, a barrier metallic layer being formed on the surface of the first metallic wiring layer; a second inter-layer insulating film which is formed on the first metallic wiring layer; a second metallic wiring layer formed on the surface of the second inter-layer insulating film at portions other than un upper portions of the photodiode; an undoped silicon glass film formed on the second metallic wiring layer containing hydrogen; and a passivation film formed on the undoped silicon glass film.

A method for manufacturing a solid-state imaging device according to an aspect of the invention includes steps of forming a photodiode on a surface of a semiconductor substrate; forming a gate electrode layer on the surface of the semiconductor substrate through a gate oxide film; forming a first inter-layer insulating film on the surface of the semiconductor substrate with the photodiode and the gate electrode layer formed thereon; forming a first metallic wiring layer formed on the surface of the first inter-layer insulating film at portions other than upper portions of the photodiode, a barrier metallic layer being formed on the surface of the first metallic wiring layer; forming a second inter-layer insulating film on the first metallic wiring layer; forming a second metallic wiring layer on the surface of the first inter-layer insulating film at portions other than upper portions of the photodiode; forming an undoped silicon glass film containing hydrogen on the second metallic wiring layer; forming a passivation film containing hydrogen on the undoped silicon glass film; and

applying heat treatments at a temperature of more than 400° C. to the semiconductor substrate on which each layer has been formed.

According to one aspect of the present invention, dark currents are fully reduced in the solid-state imaging device employing the barrier metallic wiring structure.

### BRIEF DESCRIPTION OF THE SEVERAL VIEWS OF THE DRAWING

FIG. 1 is an exemplary main-part cross-sectional view of a solid-state imaging device according to an embodiment of the invention;

FIG. 2A is an exemplary view depicting a manufacturing steps of the solid-state imaging device according to the embodiment of the invention;

FIG. 2B is another exemplary view depicting manufacturing steps of the solid-state imaging device according to the embodiment of the invention;

FIG. 2C is another exemplary view depicting manufacturing steps of the solid-state imaging device according to the embodiment of the invention;

FIG. 2D is another exemplary view depicting manufacturing steps of the solid-state imaging device according to the embodiment of the invention;

FIG. 2E is another exemplary view depicting manufacturing steps of the solid-state imaging device according to the embodiment of the invention;

FIG. 3 is an exemplary graph depicting a relation between a treatment temperature and a hydrogen exhausting quantity in the steps depicted in FIG. 2D; and

FIG. 4 is an exemplary graph depicting a comparison between measurements of dark currents in the solid-sate imaging device manufactured by a manufacturing method according to the embodiment of the present invention and of dark currents in a solid state imaging device manufactured by a conventional manufacturing method.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

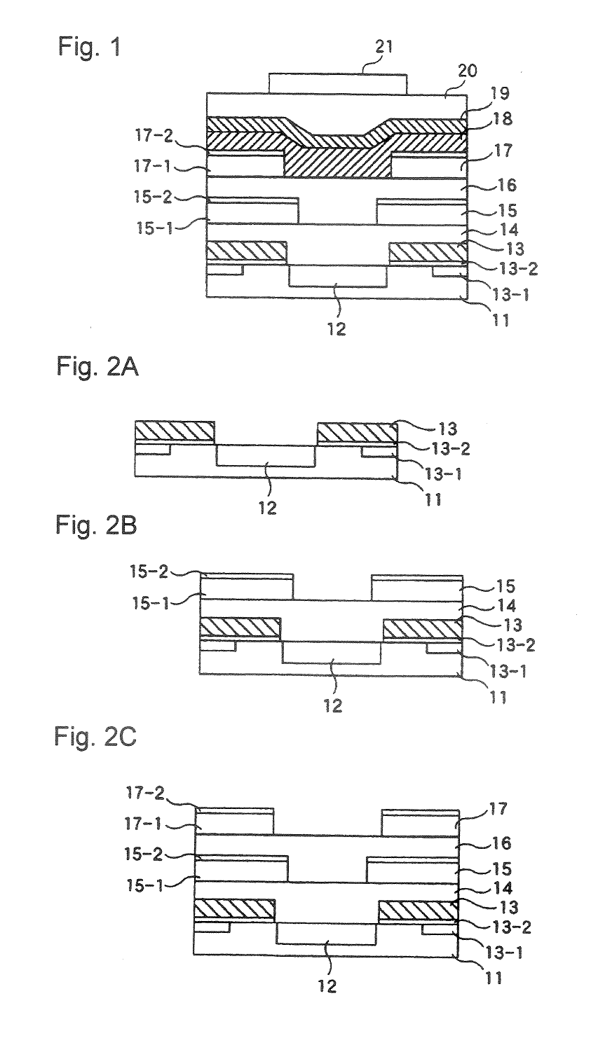

FIG. 1 is a cross-sectional view to illustrate a device structure of a solid-state imaging device according to the present invention. FIG. 1 is a cross-sectional view of the part corresponding to one pixel of the solid-state imaging device, in which a large number of pixels are arranged in linear or in plane in an actual device.

A photodiode 12 is formed on the surface of an N-type Si semiconductor substrate 11. Gate electrode layers 13 constituting a transfer gate transistor are formed on both sides of the photodiode 12. A channel layer 13-1 is formed on the surface of the semiconductor substrate 11 below the gate electrode layer 13, and a gate oxide film 13-2 made of thin SiO2 is formed between the surface of the channel layer 13-1 and the electrode layer 13. A first inter-layer insulating film 14 made of SiO2 is laminated on the surface of the semiconductor substrate 11 with the photodiode 12 and the gate electrode layer 13 formed thereon. A first metallic wiring layer 15 is formed on the surface of the second inter-layer insulating film 14 at portions other than upper portions of the photodiode. The first metallic wiring 15 consists of an Al layer 15-1 and a barrier metallic layer 15-2 composed of Ti/TiN laminated on the Al layer 15-1. Although the gate electrode layers 13 of the transfer gate transistor having been formed on the both sides of the photodiode 12 in the device described above, the gate electrode layer 13 may be formed on only one side thereof.

A second inter-layer insulating film 16 made of SiO2 is laminated on an upper surface of the first metallic wiring. A second metallic wiring layer 17 is laminated on a surface of the second inter-layer insulating film 16 at portions other than upper portions of the photodiode 12. Similarly to the first metallic wiring layer 15, the second metal wiring layer 17 is also composed of the Al layer 17-1 and of the barrier metallic layer 17-2 made of Ti/TiN laminated on an upper surface of the Al layer 17-1.

An undoped silicon glass (hereinafter it is called as USG) film 18 is formed on an upper surface of the second metallic wiring 17, and a passivation film 19 made of SiN (hereinafter referred to as SiN passivation film 19) is laminated on an upper surface of the USG film 18. Here, The USG film contains a SiO—H group, or a Si—H group.

A transparent resist layer 20 is laminated on a surface of the SiN passivation film 19, and a color filter 21 transmitting, for example, one of three primary color lights R,G or B is fixed with a transparent adhesive (not shown) on the surface of the resist layer 20 at an upper portion of the photodiode 12.

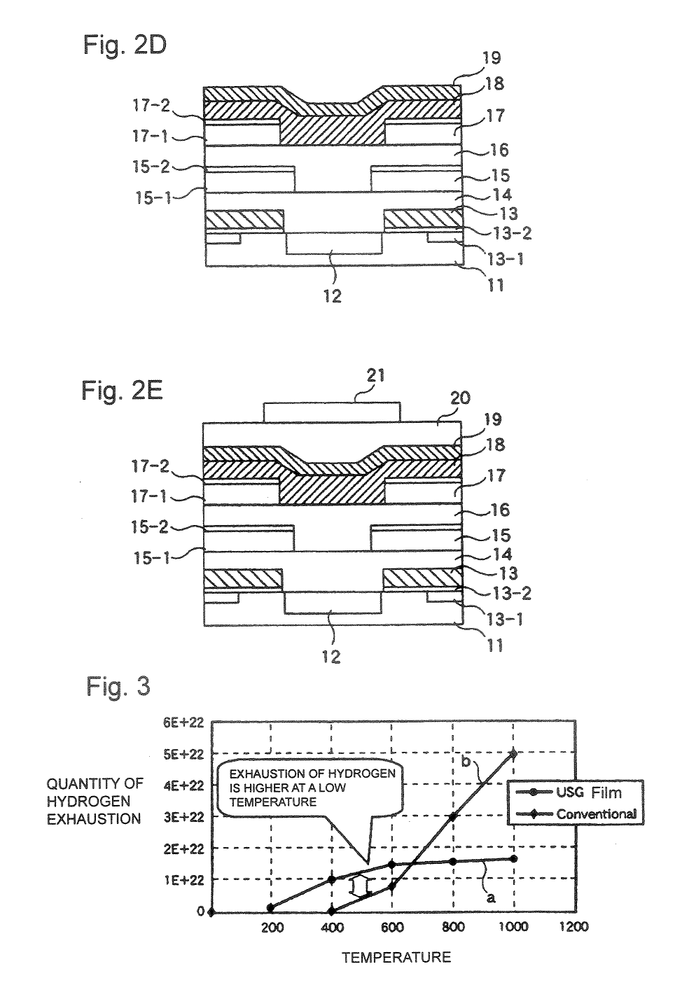

Then, a manufacturing method of the solid-state imaging device the structure described above will be described referring to FIG. 2.

P-type impurities are injected in a prescribed area on the surface of the N-type Si semiconductor substrate 11 by ion implantation and thermally diffused to form the photodiode 12, as shown in FIG. 2. The channel layer 13-1 is formed on the surface area of the semiconductor substrate 11 of the photodiode 12 by applying the thermal diffusion after the P-type impurities are injected. A thin gate oxide film 13-2 is formed by oxidizing the surface of the channel layer 13-1, and a polysilicon gate electrode layer 13 is formed on the surface thereof. The polysilicon gate electrode layer 13 is formed by providing a polysilicon layer having a thickness of 500 nm on the oxide film 13-2 and then by patterning using reactive ion etching (RIE).

The channel layer 13-1, the gate oxide film 13-2 and the gate electrode layer 13 constitutes a transfer gate transistor for reading and transferring electric charge stored in the photodiode 12, for example.

As shown in FIG. 2B, the first inter-layer insulating film 14 made of SiO2 is laminated, with a thickness of around 100 nm or more, on the surface of the N-type semiconductor substrate 11 with the photodiode 12 and the gate electrode layer 13 formed thereon. The first metallic wiring layer 15 is formed, with a thickness of around 100 nm or more, on the surface of the first inter-layer insulating film 14 at portions other than the upper portion of the photodiode 12. The first metallic wiring layer 15 is composed of the Al layer 15-1 and the barrier metal 15-2 made of the Ti/TiN layer laminated on an upper surface of the AI layer 15-1.

As indicated in FIG. 2C, the second inter-layer insulating film 16 made of SiO2 is laminated, with a thickness of around 100 nm or more, on the upper face of the first metallic wiring 15. The second metallic wiring is laminated on the surface of the second inter-layer insulating film 16, with a thickness of around 100 nm or more, at portions other than the upper portion of the photodiode 12. The second metallic wiring is also composed of the Al layer 17-1 and the barrier metal 17-2 laminated on the upper surface thereof, like the first metallic wiring 15.

On an upper surface of the second metallic wiring 17, as depicted in FIG. 2D, an USG film 18 is formed with a thickness of around 100 nm or more, and the passivation film 19 made of SiN is laminated on the further above of the second metallic wiring 17 with a thickness around 100 nm or more. Both of the USG film 18 and the SiN Passivation film 19 being formed in a CVD method and contain hydrogen with concentrations of 1.0 E21 or more each. After forming the USG film 18 and the SiN passivation film 19, the semiconductor substrate 11 is subject to a heat-treatment with temperatures from 400 to 600° C., hydrogen is exhausted from both of the USG film 18 and the SiN passivation film 19 into the semiconductor substrate 11 excessively at a concentration of 1.0 E22 or more as a whole and is diffused in the semiconductor substrate 11. Thus, the trapping function of such different atoms as impurities is reduced by bonding the hydrogen atoms to the dangling bonds in the interface of the semiconductor substrate 11, and thereby the reducing the dark currents in the solid-state imaging device dramatically.

After completing the heat treatments to the USG film 18 and to the SiN passivation film 19, a resist layer 20 is laminated on the SiN passivation film 19. A color filter 21 transmitting one of three primary color lights R,G or B, for example, is fixed with a transparent adhesive on the surface of the resist layer 20 at an upper portion corresponding to the photodiode 12 as shown in FIG. 2E.

FIG. 3 is a graph which illustrates a relation between a temperature and quantity of hydrogen exhausted in the heat treatments steps for the USG film 18 and the SiN passivation film 19, as shown in FIG. 2D. A line graph “a” in FIG. 3 indicates a relation of quantity of the hydrogen exhausted to a heat treatment temperature of the USG film 18 combined with the passivation film 19. Another line graph “b” in FIG. 3 shows a relation of quantity of the hydrogen exhausted to a heat treatment temperature in a conventional manufacturing method so as to compare it to the manufacturing method of the embodiment of the present invention. As it is cleared from FIG. 3, the quantity of the hydrogen exhausted becomes large in a rage of heat treatment temperatures from 400° C. to 600° C., and it is almost saturated at a temperature of 600° C. or higher, in the manufacturing method according to the embodiment of the present invention. In the conventional method, on the other hand, the hydrogen exhaustion starts in a range of temperatures from 400° C. to 600° C., and drastically increases in the quantity of the hydrogen exhausted. Although the quantity of the hydrogen exhausted is large, sufficient quantity of hydrogen cannot reach up to the interface of the Si semiconductor substrate 11 due to the existence of the barrier metal and to upward diffusion of the hydrogen, as mentioned above.

However, in the solid-state imaging device according to the embodiment of the present invention, it is possible to reduce the dark currents efficiently by heat treating the USG film 18 and the passivation film 19 provided above the photodiode 12, thereby efficiently supplying the interface of the semiconductor substrate 11 with the hydrogen atoms contained in the films 18 and 19 for bonding with the dangling bonds.

Further, in the solid-state imaging device according to the embodiment of the present invention, substantially whole of the hydrogen atoms exhausted from the USG film 18 through the heat treatment is supplied downward to the interface of the semiconductor substrate 11 without leaking upward, since the surface of the USG film 18 is covered with the SiN passivation film 19. That is, the passivation film 18 containing the hydrogen atoms with a high concentration compensates the quantity of the hydrogen atoms exhausted from the USG film 18, as well as it functions as a cap to prevent the hydrogen atoms exhausted from the USG film 18 from leaking upward.

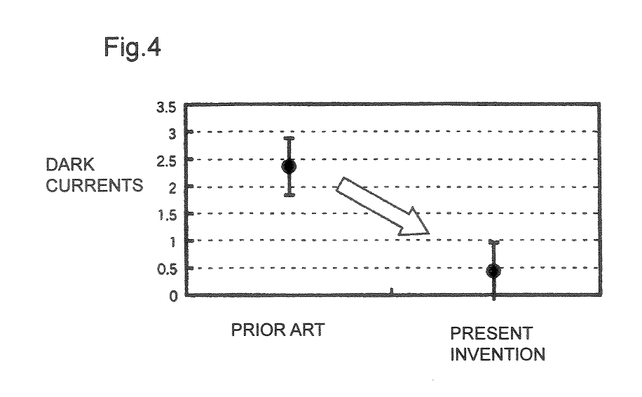

FIG. 4 is a graph comparatively showing the dark currents in the solid-state imaging device manufactured using the manufacturing method according to the embodiment of the present invention and the dark currents of the solid-state imaging device manufactured using the conventional manufacturing method. As it is clear from FIG. 4, the dark current is drastically reduced in the solid-state imaging device according to the embodiment of the present invention compared to that in the solid-state imaging device manufactured using the conventional manufacturing method.

As described, in the solid-state imaging device according to the embodiment of the present invention, it is possible to reduce the dark currents in great deal by heat treating the USG film 18 and the passivation film 19 each containing hydrogen with a high concentration at a relatively low temperature, thereby supplying the semiconductor substrate 11 with the hydrogen atoms of the high concentration.

Although the N-type semiconductor substrate 11 and the photodiode 12 of P-type are used in the embodiment described about, the present invention is also applicable to a solid-state imaging device equipped with a P-type semiconductor substrate and an N-type photodiode.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A solid-state imaging device, comprising:
a photodiode which is formed on a surface of a semiconductor substrate;
a gate electrode layer which is formed on the surface of the semiconductor substrate through a gate oxide film;
a first inter-layer insulating film which is formed on the surface of the semiconductor substrate with the photodiode and the gate electrode layer formed thereon;
a first metallic wiring layer formed on the surface of the first inter-layer insulating film at portions other than upper portions of the photodiode, a barrier metallic layer being formed on the surface of the first metallic wiring layer;
a second inter-layer insulating film which is formed on the first metallic wiring layer;
a second metallic wiring layer formed on the surface of the second inter-layer insulating film at portions other than un upper portions of the photodiode;
an undoped silicon glass film formed on the second metallic wiring layer containing hydrogen; and
a passivation film formed on the undoped silicon glass film.

2. A solid-state imaging device according to claim 1, wherein the semiconductor substrate is made of amorphous Si.

3. A solid-state imaging device according to claim 1, wherein the passivation film is made of SiN.

4. A solid-state imaging device according to claim 1, wherein the first and the second metallic insulating films are SiO2 films.

5. A solid-state imaging device according to claim 1, wherein each of the first and the second metallic wiring layers is formed with an Al layer, and with a Ti/TiN layer which is laminated on the surface of the Al layer.

6. A solid-state imaging device according to claim 1, wherein the undoped silicon glass film contains a SiO—H group or a Si—H group.

7. A solid-state imaging device according to claim 1, further comprising:
a transparent resist layer which is laminated on the surface of the passivation film; and
a color filter which is arranged on the surface of the resist layer at an upper position of the photodiode.

8. A method for manufacturing a solid-state imaging device comprising steps of:
forming a photodiode on a surface of a semiconductor substrate;
forming a gate electrode layer on the surface of the semiconductor substrate through a gate oxide film;
forming a first inter-layer insulating film on the surface of the semiconductor substrate with the photodiode and the gate electrode layer formed thereon;
forming a first metallic wiring layer formed on the surface of the first inter-layer insulating film at portions other than upper portions of the photodiode, a barrier metallic layer being formed on the surface of the first metallic wiring layer;
forming a second inter-layer insulating film on the first metallic wiring layer;
forming a second metallic wiring layer on the surface of the first inter-layer insulating film at portions other than upper portions of the photodiode;
forming an undoped silicon glass film containing hydrogen on the second metallic wiring layer;
forming a passivation film containing hydrogen on the undoped silicon glass film; and
applying heat treatments to the semiconductor substrate on which each layer has been formed.

9. A method for manufacturing a solid-state imaging device according to claim 8, wherein the heat treatments are applied at a temperature of more than 400° C.

10. A method for manufacturing a solid-state imaging device according to claim 8, wherein the semiconductor substrate is made of amorphous Si.

11. A method for manufacturing a solid-state imaging device according to claim 8, wherein the passivation film is made of SiN.

12. A method for manufacturing a solid-state imaging device according to claim 8, wherein the first and the second metallic insulating films are SiO2 films.

13. A method for manufacturing a solid-state imaging device according to claim 8, wherein the first and the second metallic wiring layers are formed with an Al layer, and with a Ti/TiN which is laminated on the surface of the Al layer.

14. A method for manufacturing a solid-state imaging device according to claim 8, wherein the undoped silicon glass film contains a SiO—H group or a Si—H group.

15. A method for manufacturing a solid-state imaging device according to claim 8, wherein the passivation film and the undoped silicon glass film contain hydrogen with a concentration of 1.0 E21 or more each.
